(19) United States
(12) Patent Application Publication
(10) Pub. No.: US 2003/0091909 A1
(43) Pub. Date: May 15, 2003

(54) Phase shift mask and fabrication method therefor

(76) Inventor: Haruo Iwasaki, Tokyo (JP)

Correspondence Address: KATTEN MUCHIN ZAVIS ROSENMAN, 575 MADISON AVENUE, NEW YORK, NY, 10022-2585, US

(21) Appl. No.: 10/283,807

(22) Filed: Oct. 30, 2002

(30) Foreign Application Priority Data
Nov. 15, 2001 (JP) 2001-350679

(51) Int. Cl. G03C 5/00; G03F 9/00

(52) U.S. Cl. 430/5; 430/322; 430/324

(57) ABSTRACT

Disclosed are a phase shift mask which has a high size precision and provides a high production yield for semiconductor devices, and a method of fabricating the same. Chrome light shielding films are formed in a predetermined pattern as light shielding films on a glass substrate, and a silicon oxide film (first phase shifter film) which has a planarized surface is formed on the entire surface of the resultant structure in such a way as to bury areas between the chrome light shielding films. A pattern of SOG (Silicon On Glass) films (second phase shifter film) is formed on the silicon oxide film. The SOG films are formed directly above the chrome light shielding films and on areas wider than the chrome light shielding films.

### BACKGROUND OF THE INVENTION

1. Field of the Invention

The present invention relates to an edge-enhanced phase shift mask and a method of fabricating the same.

2. Description of the Related Art

FIG. 1 is a cross-sectional view showing the structure of a conventional edge-enhanced phase shift mask, and FIGS. 2A to 2F are cross-sectional views showing step-by-step fabrication of the phase shift mask (see Japanese Patent Laid-open No. 282065/1994). In the conventional phase shift mask, an etching stopper film 2 is formed on a glass substrate 1 and silicon oxide films 3 are patterned on the etching stopper film 2. Then, a chrome light shielding film 4 is formed on each silicon oxide film 3.

The phase shift mask is fabricated as follows. As shown in FIG. 2A, the etching stopper film 2, the silicon oxide film 3 and the chrome light shielding film 4 are formed on the glass substrate 1. After a resist 5 is formed on the chrome light shielding film 4, a phase shift pattern is drawn on the resist 5 using a mask writing apparatus, then the resist 5 is developed to form a resist pattern as shown in FIG. 2B.

Next, as shown in FIG. 2C, with the resist pattern as a mask, the chrome light shielding film 4 and the silicon oxide film 3 are selectively removed. After the removal, the resist 5 is removed.

Then, a resist 6 is formed on the entire surface of the resultant structure after which a circuit pattern is drawn on the resist 6 using the mask writing apparatus, as shown in FIG. 2D.

Thereafter, the resist 6 is developed to form a resist pattern as shown in FIG. 2E. Then, as shown in FIG. 2F, the chrome light shielding film 4 is patterned and selectively removed using the resist pattern as a mask, thereby completing a mask formed by the chrome light shielding film 4.

According to the fabrication method for the conventional phase shift mask, the mask formed by the resist 6 has an uneven thickness and the mask thickness becomes thinner at the peripheral portion, as shown in FIG. 2E. The variation in the mask thickness at the peripheral portion changes the exposure sensitivity, and the change in exposure sensitivity lowers the precision of the pattern formation of the chrome light shielding film 4. This results in a great influence of the mask-originated variation in size, thus restricting the improvement of the yield in the fabrication process of a semiconductor device.

FIG. 3 is a cross-sectional view showing the structure of another conventional mask (see Japanese Patent Laid-Open No. 313344/1993). A chrome light shielding film 12 is formed on a glass substrate 11 and is side-etched using a resist 13, formed on the chrome light shielding film 12, as a mask. Then, a silicon oxide film 14 is formed on the glass substrate 11 by liquid-phase growth. The liquid-phase growth method forms the silicon oxide film 14 only on the glass substrate 11. The phase shift mask is a self-aligned phase shift mask which has a phase transparent area provided on at least a part of the transparent substrate.

Because the silicon oxide film 14 in the phase shift mask shown in FIG. 3 is formed in a single liquid-phase growth step, however, it is extremely difficult to control the thickness of the silicon oxide film 14 so that the required thickness precision for the oxide film needed for phase shifting cannot be acquired.

### SUMMARY OF THE INVENTION

Accordingly, it is an object of the present invention to provide a phase shift mask which has a high size precision and provides a high production yield for semiconductor devices, and a method of fabricating the same.

A phase shift mask according to the present invention comprises a transparent substrate; a pattern of light shielding films formed on the transparent substrate; a first phase shifter film having a planarized surface and formed on the transparent substrate in such a way as to cover the light shielding films and bury an area between the light shielding films; and a second phase shifter film selectively formed on the first phase shifter film above the light shielding films and on areas wider than the light shielding films.

Another phase shift mask according to the present invention comprises a transparent substrate; a pattern of light shielding films formed on the transparent substrate; a first phase shifter film having a planarized surface and formed on the transparent substrate in such a way as to cover the light shielding films and bury an area between the light shielding films; and a second phase shifter film selectively formed on the first phase shifter film above areas between the light shielding films and on areas wider than the areas between the light shielding films.

In those phase shift masks, an etching stopper film may be formed between the second phase shifter film and the first phase shifter film.

A fabrication method for a phase shift mask according to the present invention comprises the steps of forming a pattern of light shielding films on a transparent substrate; forming a first phase shifter film on an entire surface of a resultant structure and then planarizing a surface of the first phase shifter film; forming a second phase shifter film; forming a resist on the second phase shifter film; drawing a phase shift pattern on the resist by photolithography and developing the phase shift pattern to form a resist pattern; and etching and patterning the second phase shifter film using the resist pattern as a mask, whereby the second phase shifter film is selectively formed on the first phase shifter film above the light shielding films and on areas wider than the light shielding films.

Another fabrication method for a phase shift mask comprises the steps of forming a pattern of light shielding films on a transparent substrate; forming a first phase shifter film on an entire surface of a resultant structure and then planarizing a surface of the first phase shifter film; forming a second phase shifter film; forming a resist on the second phase shifter film; drawing a phase shift pattern on the resist by photolithography and developing the phase shift pattern to form a resist pattern; and etching and patterning the second phase shifter film using the resist pattern as a mask, whereby the second phase shifter film is selectively formed on the first phase shifter film above areas between the light shielding films and on areas wider than the areas between the light shielding films.

In those fabrication methods, the first phase shifter film is, for example, a silicon oxide film.

An etching stopper film may be formed between the step or forming the first phase shifter film and the step of forming the second phase shifter film. In those fabrication methods, in case where a silicon oxide film is formed as the first phase shifter film, a silicon oxide film is formed as the second phase shifter film.

An SOG film may be formed as the second phase shifter film and in case where a silicon oxide film is formed as the first phase shifter film, it is unnecessary to form an etching stopper film.

### BRIEF DESCRIPTION OF THE DRAWINGS

FIG. 1 is a cross-sectional view showing the structure of a conventional phase shift mask;

FIGS. 2A to 2F are cross-sectional views showing step-by-step fabrication of the conventional phase shift mask;

FIG. 3 is a cross-sectional view showing the structure of another conventional phase shift mask;

FIG. 4 is a cross-sectional view illustrating a phase shift mask according to a first embodiment of the invention;

FIGS. 5A to 5G are cross-sectional views illustrating a step-by-step fabrication method for the phase shift mask according to the first embodiment of the invention;

FIG. 6 is a cross-sectional view illustrating a phase shift mask according to a second embodiment of the invention;

FIGS. 7A to 7c are cross-sectional views illustrating a step-by-step fabrication method for the phase shift mask according to the second embodiment of the invention; and

FIG. 8 is a cross-sectional view illustrating a phase shift mask according to a third embodiment of the invention.

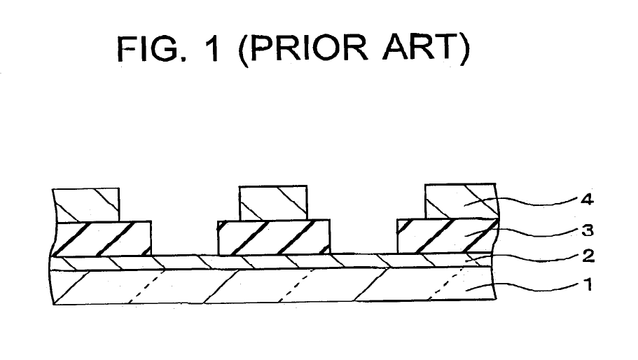

### DETAILED DESCRIPTION OF THE PREFERRED EMBODIMENTS

Preferred embodiments of the invention will be described below specifically with reference to the accompanying drawings. FIG. 4 is a cross-sectional view illustrating a phase shift mask according to the first embodiment of the invention. Chrome light shielding films 22 are formed in a predetermined pattern as light shielding films on a glass substrate 21, and a silicon oxide film 23 (first phase shifter film) which has a planarized surface is formed on the entire surface of the resultant structure in such a way as to bury areas between the chrome light shielding films 22. A pattern of SOG (Silicon On Glass) films 24 (second phase shifter film) is formed on the silicon oxide film 23. The SOG films 24 are formed directly above the chrome light shielding films 22 and on areas wider than the chrome light shielding films 22. This completes the structure of the phase shift mask.

The phase shift mask provides a phase difference of 180° at the center portion and end portion of an area which is not shielded by the chrome light shielding films 22 to thereby improve the contrast at the time of resolving the pattern. A light transmitting area between the chrome light shielding films 22 has a region where light passes only the silicon oxide film 23 and a region where light passes the silicon oxide film 23 and the SOG film 24. This can produce a phase difference of 180° at both regions, so that the edge can be enhanced.

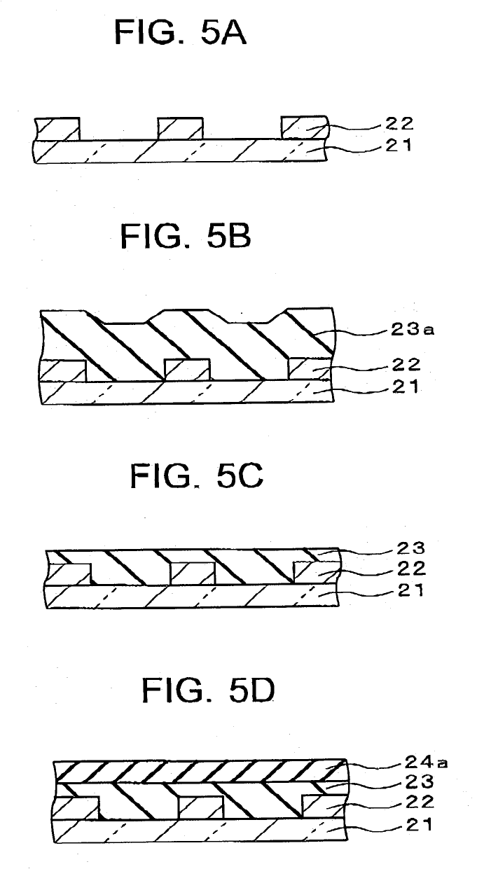

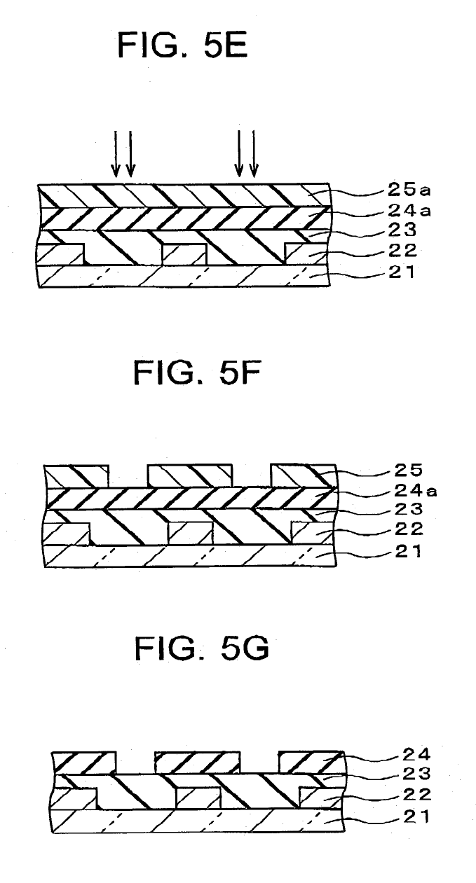

FIGS. 5A to 5G are cross-sectional views illustrating a step-by-step fabrication method for the phase shift mask according to the first embodiment of the invention. First, the circuit pattern of the chrome light shielding films 22 is formed on the glass substrate 21, thereby preparing a mask substrate, as shown in FIG. 5A.

Next, as shown in FIG. 5B, a silicon oxide film 23a is formed on the entire surface of the resultant structure by CVD (Chemical Vapor Deposition) or sputtering. The surface of the silicon oxide film 23a has undulations in which projections are portions where the circuit pattern of the chrome light shielding films 22 exists. That is, the undulations that reflect the chrome light shielding films 22 remain on the surface of the silicon oxide film 23a.

Thereafter, the surface of the silicon oxide film 23a is planarized by CMP (Chemical Mechanical Polishing), thereby forming a silicon oxide film 23 having a planarized surface, as shown in FIG. 5C.

Next, an SOG film 24a is formed on the entire surface of the silicon oxide film 23, as shown in FIG. 5D.

Then, a resist 25a is formed on the SOG film 24a as shown in FIG. 5E, and a phase shift pattern is drawn on the resist 25a by using a mask writing apparatus.

Next, the resist 25a is developed to form a pattern of resists 25, as shown in FIG. 5F.

Thereafter, with the pattern of the resists 25 used as a mask, the SOG film 24a is selectively removed to form a pattern of SOC films 24, as shown in FIG. 5G. In this case, it is preferable to use dry etching which uses a gas of CF₄ or CHF₃ in processing the SOG film. Because the SOG film has a high etching rate to a silicon oxide film, it has an advantage that an etching stopper film of ITO (Indium-Titanium Oxide) or the like need not be used. The phase shift mask according to the embodiment as illustrated in FIG. 4 is completed in the above-described manner.

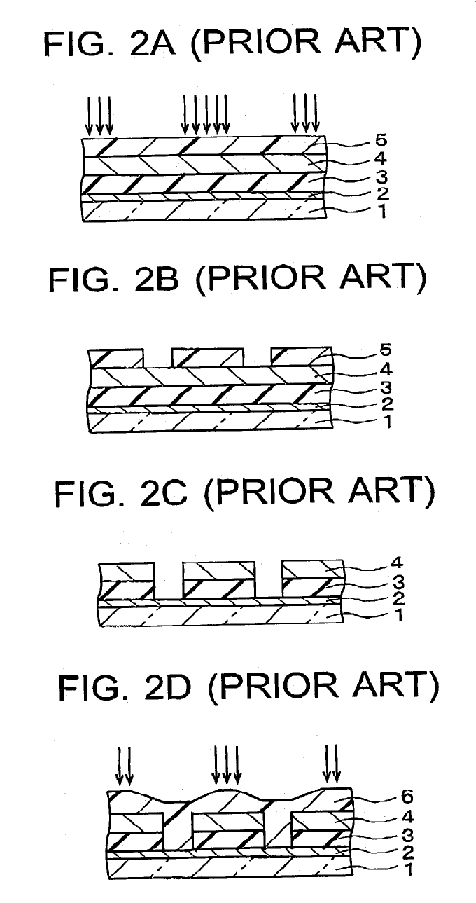

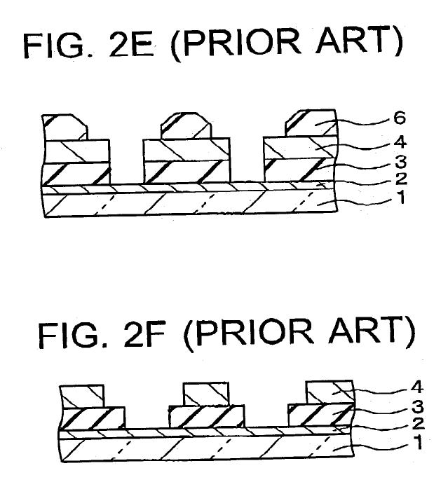

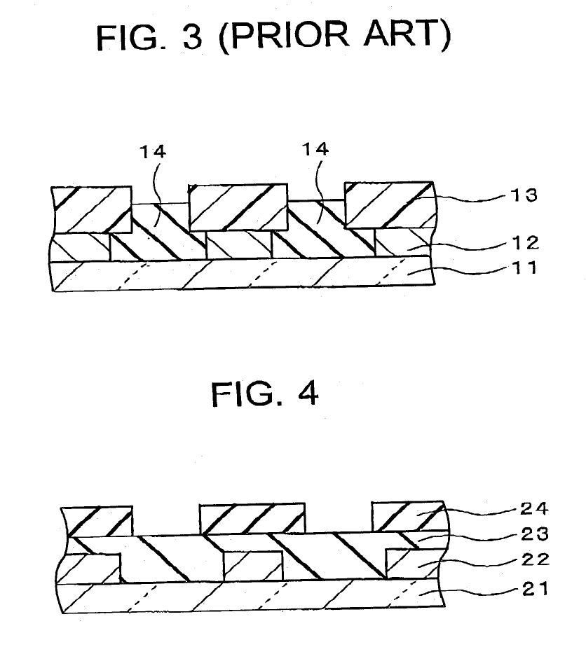

According to the conventional fabrication method, as shown in FIG. 2D, the thickness of the resist 6 formed on the mask substrate varies and the pattern of the resist 6 patterned in such a circumstance is affected by factors, such as a variation in thickness, a variation in sensitivity and the reflection from steps. If the chrome light shielding film 4 is patterned using the pattern of the resist 6, therefore, a high size precision cannot be provided.

According to the embodiment, however, as the pattern of the chrome light shielding films 22 is formed on the flat substrate as shown in FIG. 5A, the chrome light shielding films 22 has a very high size precision. The embodiment can therefore provide a phase shift mask whose chrome light shielding films 22 and SOG films 24 have extremely high size precisions.

The light shielding film is not limited to a thin metal film of chromium, but a thin metal film of nickel or the like can be used as well. The first phase shifter film is not limited to a silicon oxide film, but other materials, such as SOG, can be used. Further, the second phase shifter film is not limited to an SOG film, but other materials, such as silicon oxide, can be used.

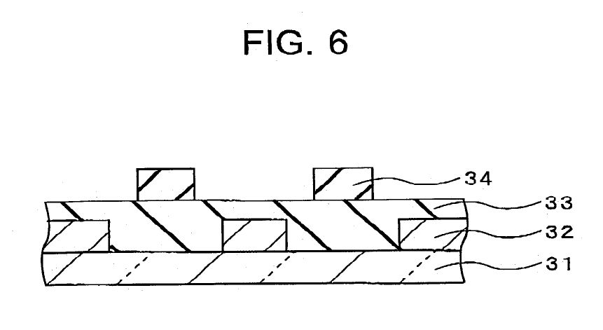

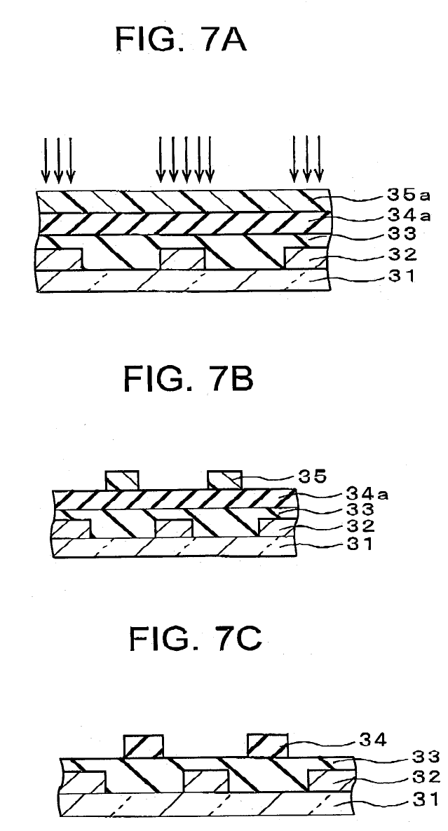

FIG. 6 is a cross-sectional view illustrating a phase shift mask according to a second embodiment of the invention, and FIGS. 7A to 7C are cross-sectional views illustrating a step-by-step fabrication method for the phase shift mask according to this embodiment. In the embodiment, a pattern or chrome light shielding films 32 is formed on a glass substrate 31, and a silicon oxide film 33 is formed on the entire surface of the resultant structure in such a way as to bury areas between the chrome light shielding films 32. A pattern of SOG films 34 is formed on the silicon oxide film 33. The SOG films 34 are formed directly above the areas between the chrome light shielding films 32 and on areas narrower than the areas between the chrome light shielding films 32. This completes the structure of the phase shift mask.

As shown in FIG. 7A, first, the phase shift mask according to the embodiment forms a layer structure similar to that in FIG. 5E. That is, through steps similar to those shown in FIGS. 5A to 5D, the chrome light shielding films 32 are formed in a predetermined pattern on the glass substrate 31, the silicon oxide film 33 is formed in such a way that the entire surface becomes flat, an SOG film 34a is formed on the silicon oxide film 33, and a resist 35a is formed on the SOG film 34a. Then, a phase shift pattern is drawn on the resist 35a by using the mask writing apparatus.

Next, a pattern of resists 35 is formed by developing the resist 35a, as shown in FIG. 7B. The pattern of the resists 35 is formed directly above the areas between the chrome light shielding films 32 and on areas narrower than the areas between the chrome light shielding films 32.

Thereafter, with the resists 35 used as a mask, the SOG film 34a is etched to form the pattern of the SOG films 34, as shown in FIG. 7C. This provides the phase shift mask that has the structure as shown in FIG. 6.

Because a pattern of chrome light shielding films also formed on the glass substrate 31 and the pattern of the SOG films 34 is formed by the resists 35 having a uniform thickness in this embodiment too, the size precision of the acquired phase shift mask is very high.

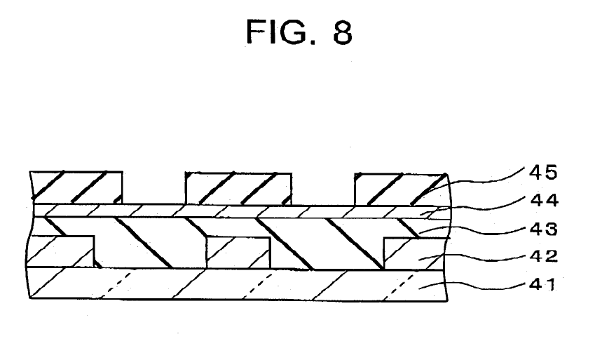

FIG. 8 is a cross-sectional view illustrating a phase shift mask according to a third embodiment of the invention. In the phase shift mask according to the embodiment shown in FIG. 8, a pattern of chrome light shielding films 42 is formed on a glass substrate 41, and a silicon oxide film 43 which has a planarized surface is formed on the entire surface of the resultant structure in such a way as to bury areas between the chrome light shielding films 42. An etching stopper film 44 is formed on the silicon oxide film 43, and a pattern of silicon oxide films 45 is formed on the etching stopper film 44. The silicon oxide films 45 are formed directly above the chrome light shielding films 42 and on areas wider than the chrome light shielding films 42. This completes the structure of the phase shift mask.

In the third embodiment, the silicon oxide films 45 are formed in place of the SOG films 24 in the first embodiment shown in FIG. 4. Therefore, there is no etching selectivity between the silicon oxide films 45 and the underlying silicon oxide film 43. At the time the silicon oxide film 45 is etched by using a mask 25 as shown in FIG. 5F, therefore, the underlying silicon oxide film 43 would be etched without the etching stopper film 44 In this respect, the etching stopper film 44 is essential in the embodiment.

As described above, the invention can fabricate a high-precision phase shift mask in which the formation precision (size precision) of the chrome light shielding films and the formation precision (size precision) of the phase-difference adjusting film for providing a phase difference of 180° in an area where light is not shielded are high. It is therefore possible to prevent a mask-originated variation in the size of semiconductor devices and improve the productional yield of the semiconductor devices.

What is claimed is:

1. A phase shift mask comprising:
a transparent substrate;
a pattern of light shielding films formed on said transparent substrate;
a first phase shifter film having a planarized surface and formed on said transparent substrate in such a way as to cover said light shielding films and bury an area between said light shielding films; and
a second phase shifter film selectively formed on said first phase shifter film above said light shielding films and on areas wider than said light shielding films.

2. A phase shift mask comprising:
a transparent substrate;
a pattern of light shielding films formed on said transparent substrate;
a first phase shifter film having a planarized surface and formed on said transparent substrate in such a way as to cover said light shielding films and bury an area between said light shielding films; and
a second phase shifter film selectively formed on said first phase shifter film above areas between said light shielding films and on areas wider than said areas between said light shielding films.

3. The phase shift mask according to claim 1, wherein an etching stopper film is formed between said second phase shifter film and said first phase shifter film.

4. The phase shift mask according to claim 2, wherein an etching stopper film is formed between said second phase shifter film and said first phase shifter film.

5. A fabrication method for a phase shift mask comprising the steps of:
forming a pattern of light shielding films on a transparent substrate;
forming a first phase shifter film on an entire surface of a resultant structure and then planarizing a surface of said first phase shifter film;
forming a second phase shifter film;
forming a resist on said second phase shifter film;
drawing a phase shift pattern on said resist by photolithography and developing said phase shift pattern to form a resist pattern; and
etching and patterning said second phase shifter film using said resist pattern as a mask,
whereby said second phase shifter film is selectively formed on said first phase shifter film above said light shielding films and on areas wider than said light shielding films.

6. A fabrication method for a phase Shift mask comprising the steps of:
forming a pattern of light shielding films on a transparent substrate;
forming a first phase shifter film on an entire surface of a resultant structure and then planarizing a surface of said first phase shifter film;
forming a second phase shifter film;
forming a resist on said second phase shifter film;
drawing a phase shift pattern on said resist by photolithography and developing said phase shift pattern to form a resist pattern; and
etching and patterning said second phase shifter film using said resist pattern as a mask,
whereby said second phase shifter film is selectively formed on said first phase shifter film above areas between said light shielding films and on areas wider than said areas between said light shielding films.

7. The fabrication method according to claim 5, wherein said first phase shifter film is a silicon oxide film.

8. The fabrication method according to claim 6, wherein said first phase shifter film is a silicon oxide film.

9. The fabrication method according to claim 5, wherein an etching stopper film is formed between said step of forming said first phase shifter film and said step of forming said second phase shifter film.

10. The fabrication method according to claim 6, wherein an etching stopper film is formed between said step of forming said first phase shifter film and said step of forming said second phase shifter film.

11. The fabrication method according to claim 7, wherein said second phase shifter film is an SOG (Silicon On Glass) film.

12. The fabrication method according to claim 8, wherein said second phase shifter film is an SOG (Silicon on Glass) film.

13. The fabrication method according to claim 9, wherein said second phase shifter film is a silicon oxide film.

14. The fabrication method according to claim 10, wherein said second phase shifter film is a silicon oxide film.
